(19) United States
(12) Patent Application Publication
(10) Pub. No.: US 2026/0190981 A1
(43) Pub. Date: Jul. 2, 2026

(54) SEMICONDUCTOR DEVICE

(71) Applicant: Samsung Electronics Co., Ltd., Suwon-si (KR)

(72) Inventors: Hangyeol Choi, Suwon-si (KR); Sunguk Jang, Suwon-si (KR); Yongjin Kim, Suwon-si (KR); Sanghoon Ahn, Suwon-si (KR); Sungjoo An, Suwon-si (KR); Minkyoung Lee, Suwon-si (KR); Woojin Lee, Suwon-si (KR)

(21) Appl. No.: 19/291,906

(22) Filed: Aug. 6, 2025

(30) Foreign Application Priority Data
Dec. 26, 2024 (KR) 10-2024-0197473

(51) Int. Cl. H01L 23/528; H01L 23/522; H01L 23/532; H10D 30/00; H10D 30/43; H10D 62/10; H10D 84/01; H10D 84/83

(52) U.S. Cl. CPC H10W 20/435; H10W 20/42; H10W 20/4441; H10W 20/47; H10W 20/495; H10D 30/43; H10D 30/502; H10D 62/121; H10D 84/0149; H10D 84/832

(57) ABSTRACT

A semiconductor device includes a substrate, transistor structures on the substrate, an interlayer insulating layer covering the transistor structures, and a wiring structure on the interlayer insulating layer, wherein the wiring structure comprises a plurality of wiring layers spaced apart from each other in a first direction, wherein the first direction is parallel to a surface of the substrate, a separation structure between a pair of adjacent wiring layers of the plurality of wiring layers, wherein the separation structure comprises a lower separation pattern and an upper separation pattern, wherein the upper separation pattern is above the lower separation pattern, and a contact via on a first wiring layer of the pair of adjacent wiring layers, wherein an upper surface of the lower separation pattern includes a dishing region that is curved toward an upper surface of the interlayer insulating layer, and wherein the upper separation pattern is within a recess formed by the dishing region.

### CROSS-REFERENCE TO RELATED APPLICATION

This application claims priority to and the benefit of Korean Patent Application No. 10-2024-0197473, filed with the Korean Intellectual Property Office on Dec. 26, 2024, the entire contents of which are incorporated herein by reference.

### BACKGROUND

A semiconductor device includes an integrated circuit including of MOS field-effect transistors (FETs). As the size and design rules of semiconductor devices are gradually reduced, the size reduction (scale down) of MOS field effect transistors and signal wires is also accelerating. As the size of MOS field effect transistors and signal wires shrinks, the operational characteristics of semiconductor devices may deteriorate. Accordingly, various methods are being researched to overcome the challenges of semiconductor device integration and to manufacture semiconductor devices with superior performance.

### SUMMARY

Some aspects of this disclosure provide semiconductor devices with improved reliability.

A semiconductor device according to some implementations may include a substrate, transistor structures on the substrate, an interlayer insulating layer covering the transistor structures, and a wiring structure on the interlayer insulating layer, wherein the wiring structure comprises a plurality of wiring layers spaced apart from each other in a first direction, wherein the first direction is parallel to a surface of the substrate, a separation structure between a pair of adjacent wiring layers of the plurality of wiring layers, wherein the separation structure comprises a lower separation pattern and an upper separation pattern, wherein the upper separation pattern is above the lower separation pattern, and a contact via on a first wiring layer of the pair of adjacent wiring layers, wherein an upper surface of the lower separation pattern includes a dishing region that is curved toward an upper surface of the interlayer insulating layer, and wherein the upper separation pattern is within a recess formed by the dishing region.

A semiconductor device according to some implementations may include a substrate, transistor structures on the substrate, an interlayer insulating layer covering the transistor structures and a wiring structure positioned on the interlayer insulating layer, wherein the wiring structure comprises a plurality of wiring layers spaced apart from each other in a first direction, wherein the first direction is parallel to a surface, a separation structure between a pair of adjacent wiring layers of the plurality of wiring layers, an air gap between the interlayer insulating layer and the separation structure, and an insulating liner between the air gap and the separation structure, wherein a surface of the insulating liner in contact with the air gap is positioned at a same level as or higher than an upper surface of a first wiring layer of the pair of adjacent wiring layers.

A semiconductor device according to some implementations may include a substrate, transistor structures on the substrate, a first interlayer insulating layer covering the transistor structures and a wiring structure on the first interlayer insulating layer, wherein the wiring structure comprises a plurality of wiring layers spaced apart from each other in a first direction, wherein the first direction is parallel to a of the substrate, a separation structure between a pair of adjacent wiring layers of the plurality of wiring layers, wherein the separation structure includes a lower separation pattern and an upper separation pattern on the lower separation pattern, and wherein an upper surface of the separation structure is positioned at a higher level than an upper surface of a first wiring layer of the pair of adjacent wiring layers, an insulating liner covering a side surface and a lower surface of the lower separation pattern, a second interlayer insulating layer covering at least a portion of the upper surface of the first wiring layer, and at least a portion of each of the upper surface and a side surface of the separation structure, a contact via extending in the second interlayer insulating layer and electrically connected to the first wiring layer, wherein the contact via, at a level higher than the upper surface of the separation structure, has a width along the first direction greater than a width of the first wiring layer along the first direction, and
wherein the contact via covers at least a portion of the upper surface of the first wiring layer and at least a portion of the upper surface of the separation structure, and a barrier layer covering a side surface and a lower surface of the contact via, wherein an air gap is between a lower surface of the separation structure and the first interlayer insulating layer, wherein an upper surface of the lower separation pattern includes a dishing region, wherein the dishing region is curved toward an upper surface of the first interlayer insulating layer, and wherein the upper separation pattern is within a recess formed by the dishing region.

A manufacturing method of a semiconductor device according to some implementations may include, forming transistor structures on a substrate, forming an interlayer insulating layer covering the transistor structures, and forming a wiring structure positioned on the interlayer insulating layer, wherein the forming the wiring structure includes forming wiring layers positioned spaced apart from each other in a first direction parallel to one surface of the substrate, forming a separation structure positioned between the wiring layers, including a lower separation pattern and an upper separation pattern on the lower separation pattern, and forming a contact via on the wiring layer, and wherein the forming the separation structure includes forming a dishing region curved in a direction toward upper surface of the interlayer insulating layer on an upper surface of the lower separation pattern, and forming the upper separation pattern within the dishing region.

In the manufacturing method of the semiconductor device, the forming the separation structure may include forming the upper separation pattern selectively on the lower separation pattern.

The manufacturing method of the semiconductor device may further include forming a hard mask pattern on the wiring layer, and wherein the forming the upper separation pattern selectively on the lower separation pattern may further include forming a deposition prevention layer on the hard mask pattern.

In the manufacturing method of the semiconductor device, an interface between a lower surface of the upper separation pattern and an upper surface of the lower separation pattern may be positioned at a level higher than an upper surface of the wiring layer.

In the manufacturing method of the semiconductor device, an upper surface of the separation structure may be positioned at a higher level than the upper surface of the wiring layer.

The method for manufacturing the semiconductor device may further include forming an air gap positioned between the interlayer insulating layer and the separating structure.

In the manufacturing method of the semiconductor device, the forming the air gap may include forming a sacrificial layer between the wiring layers, forming an insulating liner on the sacrificial layer, and removing the sacrificial layer.

In the manufacturing method of the semiconductor device, a surface of the insulating liner in contact with the air gap may be positioned at a level equal to or higher than an upper surface of the wiring layer.

Based on the foregoing and/or other characteristics as described herein, the reliability of the semiconductor device may be improved.

### BRIEF DESCRIPTION OF THE DRAWINGS

FIG. 1 is a cross-sectional view showing an example of a semiconductor device.

FIG. 2 is an enlarged cross-sectional view showing the ‘A’ region of FIG. 1.

FIG. 3 is an enlarged cross-sectional view showing the ‘B’ region of FIG. 2.

FIG. 4 is a cross-sectional view showing an example of a semiconductor device.

FIG. 5 is a cross-sectional view showing an example of a semiconductor device.

FIG. 6 is a cross-sectional view showing an example of a semiconductor device.

FIG. 7 is a cross-sectional view showing an example of a semiconductor device.

FIG. 8 is a cross-sectional view showing an example of a semiconductor device.

FIG. 9 is a cross-sectional view showing an example of a semiconductor device.

FIG. 10 to FIG. 22 are process cross-sectional views illustrating an example of a manufacturing method of semiconductor devices.

FIG. 23 to FIG. 30 are process cross-sectional views illustrating an example of a manufacturing method of semiconductor devices.

### DETAILED DESCRIPTION

As those skilled in the art would realize, the examples described below may be modified in various different ways without departing from the spirit or scope of the present disclosure.

Descriptions of some well-known parts are omitted, and like reference numerals designate like elements throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thickness of layers, films, panels, regions, etc., may be exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, in the specification, the word “on” or “above” refers to a relative positioning, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

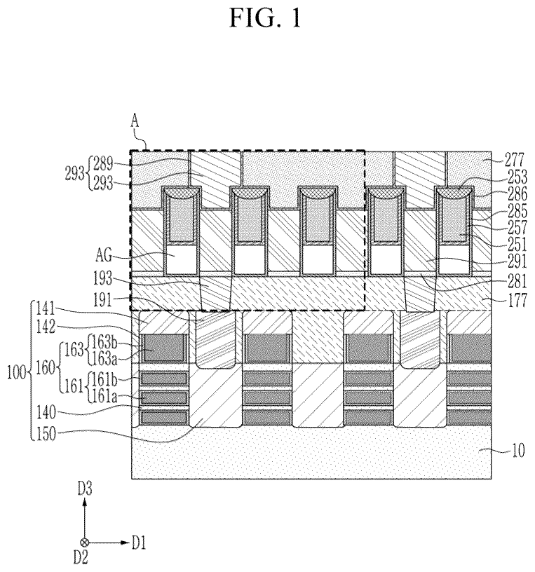

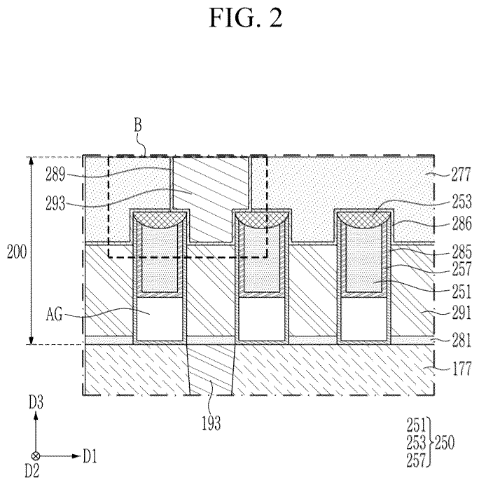

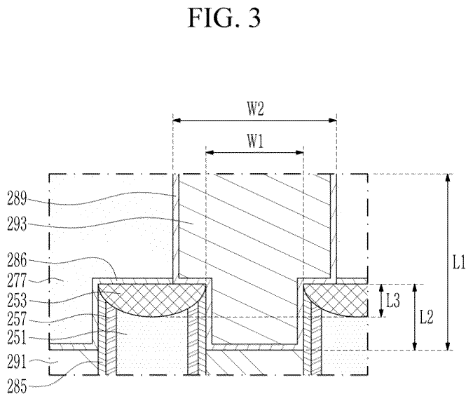

FIG. 1 to FIG. 3 are drawings for explaining examples of semiconductor devices. In detail, FIG. 1 is a cross-sectional view showing an example of a semiconductor device. FIG. 2 is an enlarged cross-sectional view of the ‘A’ region of FIG. 1. FIG. 3 is an enlarged cross-sectional view of the ‘B’ region of FIG. 2.

First, referring to FIG. 1 and FIG. 2, a semiconductor device may include a transistor structure 100 positioned on a substrate 10 and a wiring structure 200 connected to the transistor structure 100. In some implementations, the wiring structure 200 may include wiring layers 291, a separation structure 250 positioned between the wiring layers 291, and a contact via 293 positioned on the wiring layer 291 and connected to the wiring layer 291.

Substrate 10 may be silicon-on-insulator (SOI) or bulk silicon. As another example, the substrate 10 may be a silicon substrate, or may include other materials, for example, silicon germanium (SiGe), silicon germanium on insulator (SGOI), indium antimony, lead tellurium compound, indium arsenic, indium phosphide, gallium arsenic or gallium antimony, but is not limited thereto.

Substrate 10 may include an upper surface and a lower surface. The upper surface and the lower surface of the substrate 10 may be formed as planes parallel to the first direction D1 and the second direction D2 intersecting the first direction D1. The upper surface of substrate 10 may be a surface opposite to the lower surface of substrate 10 in the third direction D3. The upper surface of substrate 10 may be referred to as the front side. The lower surface of substrate 10 may be referred to as the back side.

Transistor structure 100 may be positioned on substrate 10. The transistor structure 100 may include various microelectronic devices formed in a FEOL (Front-end-of-Line) process, such as a MOSFET (metal-oxide-semiconductor field effect transistor), a system LSI (large scale integration), an image sensor such as a CIS (CMOS imaging sensor), a MEMS (micro-electro-mechanical system), active components, passive components, etc. For example, the transistor structure 100 may include a planar type MOSFET, a FinFET (Fin Field-Effect Transistor), an MBCFET (Multi-Bridge Channel Field-Effect Transistor), or a 3DSFET (three dimensional—stacked FET). Below, the transistor structure 100 will be described as an example including an MBCFET, but the semiconductor device is not limited thereto. For example, in semiconductor devices described herein, the transistor structure 100 may include a planar type MOSFET, FinFET or 3DSFET (three dimensional—stacked FET).

The transistor structure 100 may include channel patterns 140, gate structures 160 surrounding the channel patterns 140, and source/drain patterns 150 positioned on both sides of the channel patterns 140.

The channel patterns 140 may be positioned on the upper surface of substrate 10. the channel patterns 140 may be arranged spaced apart in the first direction D1 on substrate 10. Each of the channel patterns 140 may have a sheet shape. Each of the channel patterns 140 may be a nano sheet with a thickness of several nanometers along the third direction D3.

The channel patterns 140 may provide a passage for current to flow between source/drain patterns 150, described below. Referring to FIG. 1, channel pattern 140 is arranged between source/drain patterns 150, so that it may connect the source/drain patterns 150. In FIG. 1, four channel patterns 140 are illustrated as being arranged spaced apart in the third direction D3, but the number is not limited thereto, and the number of stacks of channel patterns 140 may be changed in various ways.

The channel patterns 140 may include semiconductor material. For example, the channel patterns 140 may include group IV semiconductors such as Si, Ge, group III-V compound semiconductors, group II-VI compound semiconductors, etc.

The gate structure 160 may be positioned on substrate 10. The gate structure 160 may extend in the second direction D2 on the substrate 10. The gate structure 160 may be positioned on substrate 10. The gate structures 160 may be arranged spaced apart from each other in the first direction D1. The gate structure 160 may include sub-gate structure 161 and main gate structure 163.

The sub-gate structures 161 and the channel patterns 140 may be alternately stacked in the third direction D3. In FIG. 1, three sub-gate structures 161 are depicted as arranged spaced apart in the third direction D3, but the number of sub-gate structures 161 arranged spaced apart is not limited thereto. For example, the gate structure 160 may include four sub-gate structures 161.

The sub-gate structure 161 may include a sub-gate electrode 161a and a sub-gate insulation layer surrounding it. The sub-gate electrode 161a may be positioned on the substrate 10. A plurality of sub-gate electrodes 161a may be positioned spaced apart from each other on substrate 10. A plurality of sub-gate electrodes 161a and a plurality of channel patterns 140 may be alternately and repeatedly stacked.

The sub-gate electrode 161a may include at least one of a metal, a metal alloy, a conductive metal nitride, a metal silicide, a doped semiconductor material, a conductive metal oxide, or a conductive metal nitride. Sub-gate electrode 161a may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium(Ru), titanium aluminum(TiAl), titanium aluminum carbonizationnitride (TiAlC—N), titanium aluminum carbide (TiAlC), titanium carbide (TiC), tantalum carbonizationnitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but is not limited thereto.

The sub-gate insulation layer 161b may be positioned along the circumference of a plurality of channel patterns 140. The sub-gate insulation layer 161b may be interposed between a plurality of channel patterns 140 and the sub-gate electrode 161a. The sub-gate insulation layer 161b may include a variety of insulating materials.

The sub-gate insulation layer 161b is depicted as a single film, but its structure not limited thereto. For example, the sub-gate insulation layer 161b may be composed of a multilayer including silicon oxide (SiO₂) and a high dielectric constant material. The high dielectric constant material may include a material with a higher dielectric constant than silicon oxide (SiO₂), such as hafnium oxide (HfO), aluminum oxide (AlOx), or tantalum oxide (TaO).

The main gate structure 163 may be positioned on top of the sub-gate structure 161 and a plurality of channel patterns 140. The sub-gate structure 161 may be positioned on the upper surface of the channel pattern 140 positioned at the uppermost position among the plurality of channel patterns 140.

The main gate structure 163 may include a main gate electrode 163a and a main gate insulation layer 163b.

The main gate electrode 163a may be positioned on the sub-gate structure 161 and a plurality of channel patterns 110a, 110b, 110c, 110d. At least a portion of the main gate electrode 163a may be positioned on a structure in which the sub-gate electrode 161a and a plurality of channel patterns 110a, 110b, 110c, 110d are alternately stacked. The remaining part of the main gate electrode 163a may cover the side of the structure in which the sub-gate electrode 161a and the plurality of channel patterns 110a, 110b, 110c, 110d are alternately stacked. Each of the plurality of channel patterns 110a, 110b, 110c, 110d may be surrounded by a sub-gate electrode 161a and/or a main gate electrode 163a.

The main gate electrode 163a may include the same material as the sub-gate electrode 161a. For example, the main gate electrode 163a may include at least one of a metal, a metal alloy, a conductive metal nitride, a metal silicide, a doped semiconductor material, a conductive metal oxide, or a conductive metal nitride.

The main gate insulation layer 163b may extend along the side of the main gate electrode 163a. The main gate insulation layer 163b may extend along the side of the gate spacer 142, described below. The main gate insulation layer 163b may contain a variety of insulating materials. The main gate insulation layer 163b may include the same material as the sub-gate insulation layer 161b.

The main gate insulation layer 163b is depicted as a single film, but its structure is not limited thereto. For example, the main gate insulation layer 163b may be composed of a multilayer including silicon oxide SiO₂ and a high dielectric constant material. The high dielectric constant material may include a material with a higher dielectric constant than silicon oxide SiO₂, such as hafnium oxide (HfO), aluminum oxide (AlOx), or tantalum oxide (TaO).

The transistor structure 100 may further include a capping layer 141 and a gate spacer 142.

Gate spacer 142 may be positioned on the side of the main gate electrode 163a. Gate spacer 142 may be positioned above channel pattern 140. Gate spacer 142 may not be positioned on the side surface of sub-gate electrode 161a. Gate spacer 142 may not be positioned on each side of channel patterns 140. Gate spacer 142 may not be positioned between a plurality of channel patterns 140. Gate spacer 142 may not be positioned between a plurality of channel patterns 140 adjacent to the third direction D3. Gate spacer 142 is described as a single layer, but this is only for better understanding and ease of description, and its structure is not limited thereto.

Gate spacer 142 may include, for example, at least one of silicon nitride (SiNₓ), silicon oxynitride (SiON), silicon oxide (SiO₂), silicon carbonatenitride (SiOCN), silicon boronnitride (SiBN), silicon boronnitride (SiOBN), silicon oxycarbide (SiOC), or a combination thereof.

The capping layer 141 may be positioned on the main gate structure 163 and the gate spacer 142. In some implementations, the capping layer 141 may also be positioned between the gate spacers 142.

The capping layer 141 may include, for example, at least one of silicon nitride (SiN), silicon oxynitride (SiON), silicon (Si) carbonizationnitride (SiCN), silicon carbonatenitride (SiOCN), or a combination thereof.

The source/drain patterns 150 may be positioned on the upper surface of substrate 10. The channel patterns 140 and gate structures 160 may be positioned between source/drain patterns 150. A plurality of source/drain patterns 150 and a plurality of channel patterns 140 may be alternately arranged along the first direction D1.

The source/drain pattern 150 may be positioned on either side of the channel patterns 140, or the sub-gate structure 161. The two source/drain patterns 150 may be arranged spaced apart in the first direction D1, with channel patterns 140 and/or sub-gate structures 161 between them. The source/drain pattern 150 may make direct contact with the channel patterns 140 or the sub-gate structure 161. The source/drain pattern 150 may make direct contact with the sub-gate insulation layer 161b of the sub-gate structure 161.

The source/drain pattern 150 may be composed of an epitaxial layer formed by selective epitaxial growth (selective epitaxial growth; SEG). The source/drain patterns 150 may be formed by removing at least some areas of the channel patterns stacked on the substrate 10 and then selectively epitaxially growing material in the corresponding regions.

The source/drain pattern 150 may include semiconductor material. The source/drain pattern 150 may include, for example, silicon (Si) or germanium (Ge). As another example, the source/drain pattern 150 may include a binary compound or a ternary compound including at least two or more of, for example, carbon (C), silicon (Si), germanium (Ge), or tin (Sn). For example, source/drain pattern 150 may include silicon (Si), silicon-germanium (SiGe), germanium (Ge), silicon carbide (SiC), etc., but is not limited thereto.

The semiconductor device may further include an interlayer insulating layer 177, a contact electrode 191, and a contact via 193.

The interlayer insulating layer 177 may cover the source/drain pattern 150, the gate structure 160, the capping layer 141, and the gate spacer 142.

The interlayer insulating layer 177 may include an insulating material. The interlayer insulating layer 177 may include, for example, at least one of silicon oxide SiO₂, silicon nitride (SiN), silicon oxynitride (SiON), or a low dielectric constant material. Low dielectric constant materials include, for example, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride silicate glass), polyimide nanofoams such as polypropylene oxide, CDO (Carbon Doped silicon Oxide), OSG (Organo) silicate glass), SiLK, Amorphous Fluorinated Carbon, silica aerogels, silica xerogels, mesoporous silica or a combination thereof, but is not limited thereto.

Contact electrode 191 may be positioned on the source/drain pattern 150. Contact via 193 may be positioned on contact electrode 191. Contact via 193 may be connected to wiring structure 200, which will be described later. The contact electrode 191 and the contact via 193 are connected to the source/drain pattern 150, and may provide an electrical signal or power source voltage provided from the outside to the source/drain pattern 150.

The contact electrode 191 and the contact via 193 may include at least one of a metal, a metal alloy, a conductive metal nitride, a metal silicide, a doped semiconductor material, a conductive metal oxide, or a conductive metal nitride.

The wiring structure 200 may be positioned on the interlayer insulating layer 177. The wiring structure 200 may include various wiring, via, and/or insulation layers formed in the back-end-of-line (BEOL) process. The wiring structure 200 may be used to apply electric signals to the transistor structure 100 or for internal signal routing. The wiring structure 200 may include wiring layers 291, a separation structure 250 positioned between the wiring layers 291, and a contact via 293 positioned above the wiring layer 291 and connected to the wiring layer 291.

The wiring layer 291 may be positioned above transistor structure 100. The wiring layer 291 may be electrically connected to the transistor structure 100. The wiring layer 291 may be electrically connected to the transistor structure 100 through the contact via 193 and the contact electrode 191. In FIG. 1 and FIG. 2, wiring layer 291 is described as being connected to source/drain pattern 150, but is not limited thereto. For example, the wiring layer 291 may be connected to the gate structure 160 through structures such as the contact electrode 191 and the contact via 193.

At least a portion of the wiring layer 291 may have a line shape that extends in one direction. For example, wiring layer 291 may have a line shape extending in the second direction D2. In another cross-section, the wiring layer 291 may be extended in the first direction D1.

A semiconductor device may include a plurality of wiring layers 291. A plurality of wiring layers 291 may be positioned spaced apart from each other along the first direction D1. A plurality of wiring layers 291 may each be applied with different electrical signals. Referring to FIG. 1 and FIG. 2, although the wiring layer 291 is depicted as being positioned directly above the interlayer insulating layer 177, in some implementations a plurality of other wiring layers may be positioned between the wiring layer 291 and the interlayer insulating layer 177.

The wiring layer 291 may include conductive material. For example, the wiring layer 291 may include at least one of a metal, a metal alloy, a conductive metal nitride, a conductive metal carbide, a conductive metal oxide, a conductive metal nitride, and a two-dimensional 2D material. In some implementations, the wiring layer 291 may include a conductive material that is applicable to a subtractive patterning process, but is not limited thereto. For example, wiring layer 291 may include at least one of Ru, Al, W, Mo, Ti, Cr, or Ni. However, the material is not limited thereto, and the wiring layer 291 may also include, for example, Cu.

An adhesive layer 281 may be positioned between the wiring layer 291 and the interlayer insulating layer 177, and/or between the wiring layer 291 and the contact via 193. The adhesive layer 281 may be formed between the wiring layer 291 and the interlayer insulating layer 177, or between the wiring layer 291 and the contact via 193, in order to enhance the adhesion of the wiring layer 291 with other layers in the process of forming the wiring layer 291. The adhesive layer 281 may include a conductive material. For example, the adhesive layer 281 may include, Taan, TiN, WN, TaO, TiO, MnN, MnO, or a combination thereof, but is not limited thereto.

In some implementations, the semiconductor device may not include an adhesive layer 281. In this case, wiring layer 291 may contact via 193. The lower surface of wiring layer 291 may contact the upper surface of contact via 193. In some implementations, wiring layer 291 may include the same material as contact via 193. In this case, the boundary between wiring layer 291 and contact via 193 may not be recognized.

A first insulating liner 285 may be positioned on at least some regions of the side surface of the wiring layer 291 and at least some regions of the upper surface of the interlayer insulating layer 177. The first insulating liner 285 may be used to enhance the adhesion between the wiring layer 291 and other layer and to prevent oxidation of the wiring layer 291. In some implementations, the first insulating liner 285 may include a variety of insulating materials, such as silicon oxide SiO₂, silicon nitride (SiNₓ), silicon oxynitride (SiON), or silicon oxycarbide (SiOC).

The separate structure 250 may be positioned between wiring layers 291. The separation structure 250 may include a lower separation pattern 251 and an upper separation pattern 253 positioned on the lower separation pattern 251. The separation structure 250 is positioned between each of the wiring layers 291, thereby physically and electrically separating the wiring layers 291 each other.

In some implementations, the upper surface of the separation structure 250 may be positioned at a higher level than the upper surface of the wiring layer 291. The upper surface of the separation structure 250 may be positioned further from the upper surface of the substrate 10 than the upper surface of the wiring layer 291. For example, the difference between the level at which the upper surface of the separation structure 250 is positioned and the level at which the upper surface of the wiring layer 291 is positioned may be greater than about 0 nm and less than or equal to about 10 nm. For example, the upper surface of the separation structure 250 may be positioned between the upper surface of the wiring layer 291 and the upper surface of the interlayer insulating layer 277, which will be described later. For example, referring to FIG. 3, the ratio of the distance L2 between the level at which the upper surface of the separation structure 250 is positioned and the level at which the upper surface of the wiring layer 291 is positioned, to the distance L1 between the upper surface of the wiring layer 291 and the upper surface of the interlayer insulating layer 277, may be greater than or equal to about 0.1 and less than or equal to about 0.5.

In some implementations, a ratio of a maximum distance L3 in the third direction D3 between the upper surface and the lower surface of the upper separation pattern 253, to the distance L2 between the level at which the upper surface of the separation structure 250 is positioned and the level at which the upper surface of the wiring layer 291 is positioned, may be greater than or equal to about 0.3 and less than or equal to about 1.0.

In some implementations, the separation structure 250 may have a ‘DoD (dielectric on dielectric)’ structure. The separation structure 250 may include a lower separation pattern 251 and an upper separation pattern 253 positioned above the lower separation pattern 251.

The lower separation pattern 251 may be positioned on the interlayer insulating layer 177. In some implementations, a portion of the lower separation pattern 251 may overlap the wiring layer 291 in the horizontal direction (e.g., first direction D1, or second direction D2 in FIG. 1 and FIG. 2). In some implementations, the upper surface of the lower separation pattern 251 may be positioned at a higher level than the upper surface of the wiring layer 291. In some implementations, the lower surface of the lower separation pattern 251 may be positioned at a level between the upper and lower surfaces of the wiring layer 291.

Referring to FIG. 1 and FIG. 2, only some regions of wiring layer 291 may overlap with the lower separation pattern 251 in the horizontal direction (e.g., in FIG. 1 and FIG. 2, first direction D1, or second direction D2), but is not limited thereto. In the embodiment, an air gap AG may be positioned between the lower separation pattern 251 and the interlayer insulating layer 177. This will be explained later.

In some implementations, the lower separation pattern 251 may include a dishing region on the upper surface (the upper surface may include the dishing region). The dishing region may be formed by polishing the upper surface of the lower separation pattern 251 under predetermined process conditions, for example, using a chemical mechanical polishing (CMP) process, in the process of forming the lower separation pattern 251. However, the fabrication process is not limited thereto, and the dishing region may be formed using various known etching, polishing, or photo processes. Referring to FIGS. 1 and 2, the lower separation pattern 251 may have a shape in which its upper surface is curved toward the upper surface of the interlayer insulating layer 177, e.g., a concave shape. The lower separation pattern 251 may have its central portion of the upper surface of the lower separation pattern 251 positioned closer to the upper surface of the interlayer insulating layer 177 compared to both opposite lateral ends of the upper surface of the lower separation pattern 251. The upper surface of the lower separation pattern 251 may have a surface profile in which the distance to the upper surface of the interlayer insulating layer 177 gradually decreases from both ends toward the center when viewed in cross-section.

The lower separation pattern 251 may include an insulating material. For example, the lower separation pattern 251 may include at least one of silicon oxide SiO₂, silicon nitride (SiNₓ), silicon oxynitride (SiON), and silicon carbon oxide (SiOC). However, the material is not limited thereto, and the lower separation pattern 251 may include various insulating materials.

In some implementations, the separation structure 250 may further include a second insulating liner 257. A second insulating liner 257 may be positioned on least some regions of the lower surface and side surface of the lower separation pattern 251. In some implementations, the second insulating liner 257 may be for forming an air gap AG between the separating structure 250 and the interlayer insulating layer 177. The second insulating liner 257 may cover at least some regions of the lower surface and side surface of the lower separation pattern 251. The second insulating liner 257 may not be positioned on the upper surface of the lower separation pattern 251.

The second insulating liner 257 may contain an insulating material. In some implementations, the second insulating liner 257 may include a low-k material. For example, the second insulating liner 257 may include an insulating material having a lower dielectric constant than silicon oxide SiO₂. For example, the second insulating liner 257 may include aluminum oxide (Al2O3) or silicon dioxide (SiOC). However, the material is not limited thereto, and the second insulating liner 257 may include various insulating materials such as silicon oxide SiO₂, silicon nitride (SiNₓ) or silicon oxide nitride (SiON). In some implementations, the separation structure 250 may not include a second insulating liner 257.

The upper separation pattern 253 may be positioned on the lower separation pattern 251. The upper separation pattern 253 may fill the dishing region formed on the upper surface of the lower separation pattern 251. The upper separation pattern 253 may have a convex shape with the lower surface facing in a downward direction (in FIG. 1 and FIG. 2, the direction toward the upper surface of the interlayer insulating layer 177). The upper separation pattern 253 may have a central portion of the lower surface of the upper separation pattern 253 positioned closer to the upper surface of the interlayer insulating layer 177 compared to both opposite lateral ends of the lower surface of the upper separation pattern 253.

The lower surface of the upper separation pattern 253 may have a surface profile in which the distance to the upper surface of the interlayer insulating layer 177 gradually decreases from both ends toward the center when viewed in cross-section.

In some implementations, the lower surface of the upper separation pattern 253 may contact the upper surface of the lower separation pattern 251. In some implementations, the interface between the lower surface of the upper separation pattern 253 and the upper surface of the lower separation pattern 251 may be positioned at a higher level than the upper surface of the wiring layer 291. In some implementations, the interface between the lower surface of the upper separation pattern 253 and the upper surface of the lower separation pattern 251 may be positioned at substantially the same level as the upper surface of the wiring layer 291, or may be positioned at a level lower than the upper surface of the wiring layer 291. For example, a lowermost portion of an entire interface between the lower surface of the upper separation pattern 253 and the upper surface of the lower separation pattern 251 may be positioned at substantially the same level as the upper surface of the wiring layer 291, or may be positioned at a level lower than the upper surface of the wiring layer 291.

In some implementations, the upper surface of the upper separation pattern 253 may have a flat shape. However, it is not limited thereto, and the upper separation pattern 253 may have a shape that is convex upwards or convex downwards.

In some implementations, the upper separation pattern 253 may overlap the lower separation pattern 251 in the thickness direction (e.g., third direction D3 in FIG. 1 and FIG. 2, e.g., a vertical direction), but may not overlap the wiring layer 291 in the thickness direction. The upper separation pattern 253 may not include a region that overlaps with the wiring layer 291 in a direction perpendicular to the upper surface of the wiring layer 291.

In some implementations, in the process of forming the upper separation pattern 253, the upper separation pattern 253 may be formed only on the upper surface of the lower separation pattern 251, and may not be formed in a region that overlaps the wiring layer 291 along the third direction D3. This may be due to process characteristics in which the upper separation pattern 253 is formed while filling the dishing region formed on the upper surface of the lower separation pattern 251 during the formation process of the upper separation pattern 253. For example, during the process of forming the upper separation pattern 253, the opposite lateral ends of the dishing region may prevent the upper separation pattern 253 from growing or being deposited beyond or substantially beyond a region that overlaps with the lower separation pattern 251, the second insulating liner 257, and/or the first insulating liner 285 in the third direction D3, e.g., prevents growth into a region that overlaps with the wiring layer 291 in the third direction D3. Accordingly, in some implementations, the upper separation pattern 253 may be stably formed only in a region overlapping the lower separation pattern 251, the second insulating liner 257, and/or the first insulating liner 285 in the third direction D3.

The upper separation pattern 253 may include an insulating material. For example, the upper separation pattern 253 may include at least one of silicon dioxide (SiOC), silicon oxide (SiOₓ), aluminum oxide (AlOx), aluminum silicon oxide (AlSiOₓ), hafnium oxide (HfOₓ), and zirconium oxide (ZrOₓ). However, the material is not limited thereto, and the upper separation pattern 253 may include various insulating materials such as silicon nitride (SiNₓ) and/or silicon oxide nitride (SiON). In some implementations, the upper separation pattern 253 may include an insulating material having a lower dielectric constant than silicon oxide SiO₂.

In some implementations of a semiconductor device, an air gap AG may be positioned in at least a portion of a region between wiring layers 291. Air gap AG may refer to the empty space positioned between one layer and another. For example, the air gap AG may include air, or a gas used in the manufacturing process of a semiconductor device. A plurality of wiring layers 291 may be positioned horizontally apart from each other with an air gap AG and/or a separation structure 250 interposed therebetween. In some implementations, a second insulating liner 257 may be positioned between the air gap AG and the lower separation pattern 251. Referring to FIG. 2, the surface of the second insulating liner 257 in contact with the air gap AG may be positioned at a level lower than the upper surface of the wiring layer 291. However, the arrangement is not limited thereto, and the surface of the second insulating liner 257 in contact with the air gap AG may be positioned higher than the upper surface of the wiring layer 291, or at substantially the same level.

Referring to FIG. 1 and FIG. 2, an air gap AG may be positioned between the wiring layers 291 and between the separating structure 250 and the interlayer insulating layer 177. In some implementations, the wiring layer 291 may at least partially overlap with the air gap AG in a horizontal direction.

In some implementations, the air gap AG may have a lower permittivity compared to insulating material(s) included in the insulation layers and insulating patterns positioned around it. For example, the air gap AG may have a relatively lower permittivity compared to the interlayer insulating layers 177 and 277, the insulating liners 257 and 285, and the separating structure 250. For example, the air gap AG may be filled with air, and the permittivity of air may be about 1. The semiconductor device may include an air gap AG inside, thereby reducing parasitic capacitance within the device and improving its electrical characteristics.

The semiconductor device may further include an etching stop layer 286 covering a upper surface of the wiring layer 291 and a upper surface and a portion of a side surface of the separation structure 250. The etching stop layer 286 may prevent the wiring layer 291 and/or the separation structure 250 from being damaged by an etching agent, etc., when a portion of the interlayer insulating layer 277 is etched in the process of forming the contact via 293, which will be described later.

The etching stop layer 286 may cover the entire upper surface of the wiring layer 291. The etching stop layer 286 may cover at least a portion of a region of the separation structure 250 positioned at a level higher than the upper surface of the wiring layer 291. The etching stop layer 286 may cover the side surface of the separation structure 250 positioned at a higher level than the upper surface of the wiring layer 291. The etching stop layer 286 may cover at least a portion of the upper surface of the separation structure 250. The etching stop layer 286 may not be positioned in the region where the wiring layer 291 and the separation structure 250 overlap with the contact via 293 and the barrier layer 289 in the third direction D3. In some implementations, the etching stop layer 286 may be omitted.

The etching stop layer 286 may include an insulating material. The etching stop layer 286 may include an insulating material having etch selectivity with respect to the interlayer insulating layer 277. In some implementations, the etching stop layer 286 may include aluminum oxide (AlOx), aluminum nitride (AlN), or the like, but is not limited thereto.

The semiconductor device may further include an interlayer insulating layer 277 covering the wiring layer 291 and the separation structure 250.

The semiconductor device may further include an interlayer insulating layer 277 covering the wiring layer 291 and the separation structure 250.

The interlayer insulating layer 277 may be positioned on the wiring layer 291 and the separation structure 250. The interlayer insulating layer 277 may cover the entire upper surface of the wiring layer 291. Referring to FIG. 1 and FIG. 2, the etching stop layer 286 may be interposed between the lower surface of the interlayer insulating layer 277 and the upper surface of the wiring layer 291.

The interlayer insulating layer 277 may cover at least a portion of a region of the separation structure 250 positioned at a level higher than the upper surface of the wiring layer 291. The interlayer insulating layer 277 may cover the side surface of the separation structure 250 positioned at a level higher than the upper surface of the wiring layer 291. The interlayer insulating layer 277 may cover at least a portion of a region of the upper surface of the separation structure 250. Referring to FIG. 1 and FIG. 2, an etching stop layer 286 may be interposed between the interlayer insulating layer 277 and the lower separation pattern 251, or between the interlayer insulating layer 277 and the upper separation pattern 253.

The interlayer insulating layer 277 may include an insulating material. For example, interlayer insulating layer 277 may include the same insulating material as interlayer insulating layer 177, but is not limited thereto. The interlayer insulating layer 277 may include, for example, at least one of silicon oxide SiO₂, silicon nitride (SiNx), silicon oxycarbide (SiOC), silicon oxynitride (SiON), or a low dielectric constant material.

Contact via 293 may be connected to wiring layer 291. For example, the semiconductor device may further include a plurality of wiring layers positioned over the interlayer insulating layer 277. In some implementations, the contact via 293 may connect a wiring layer 291 positioned below the interlayer insulating layer 277 to at least one other wiring layer positioned on the interlayer insulating layer 277.

The contact via 293 may penetrate a region of the interlayer insulating layer 277. The contact via 293 may overlap one or more regions with wiring layer 291 and third direction D3. In some implementations, the width along the first direction D1 of the contact via 293 may not be constant. Referring to FIG. 3, contact via 293 may have a first width W1 at a level lower than the upper surface of the separation structure 250, and a second width W2 wider than the first width W1 at a level higher than the upper surface of the separation structure 250. In some implementations, the first width W1 may be substantially the same as the width along the first direction D1 of wiring layer 291. In some implementations, the second width W2 may be wider than the width along the first direction D1 of the wiring layer 291. In some implementations, the contact via 293 may cover at least a portion of the upper surface of the wiring layer 291 and at least a portion of the upper surface of the separation structure 250. The upper surface of the edge of the separation structure 250 adjacent to the wiring layer 291 may be covered by the contact via 293.

As illustrated in FIG. 1 to FIG. 3, since the upper surface of the separation structure 250 is positioned at a higher level compared to the upper surface of the wiring layer 291, the contact via 293 may include a bent or stepped portion due to the difference in width at the interface with the upper surface of the separation structure 250.

Contact via 293 may include conductive material. For example, contact via 293 may include at least one of a metal, a metal alloy, a conductive metal nitride, a metal silicide, a doped semiconductor material, a conductive metal oxide, or a conductive metal nitride. For example, contact via 293 may include Cu, Al, Ru, Co, W, and Mo, or combination thereof. However, the material is not limited thereto, and contact via 293 may include various conductive materials.

The semiconductor device may further include a barrier layer 289 surrounding the contact via 293. For example, barrier layer 289 may be positioned between contact via 293 and interlayer insulating layer 277, between contact via 293 and separation structure 250, and/or between contact via 293 and wiring layer 291. The barrier layer 289 may be in direct contact with the wiring layer 291, the separation structure 250, and the interlayer insulating layer 277. The barrier layer 289 may improve the adhesion characteristics between the contact via 293 and the interlayer insulating layer 277, between the contact via 293 and the separating structure 250, and/or between the contact via 293 and the wiring layer 291. The barrier layer 289 may prevent the material included in the contact via 293 from diffusing into the interlayer insulating layer 277 and/or the separation structure 250. In some implementations, at least some regions of barrier layer 289 may be omitted. In some implementations, the barrier layer 289 may not be positioned between the upper surface of the wiring layer 291 and the bottom surface of the contact via 293.

The barrier layer 289 may include a conductive material. For example, barrier layer 289 may include, but is not limited to, TaN, TiN, WN, TaO, TiO, MnN, MnO, or a combination thereof.

As illustrated in FIG. 1 to FIG. 3, since the upper surface of the separation structure 250 is positioned at a higher level compared to the upper surface of the wiring layer 291, the surface of the contact via 293 adjacent the upper surface of the separation structure 250 may be positioned at a higher level than the surface of the contact via 293 adjacent the upper surface of the wiring layer 291. In this case, compared to the case where the upper surface of the separation structure 250 and the upper surface of the wiring layer 291 are positioned at the same level, the distance between the contact via 293 and another wiring layer adjacent thereto (i.e., another wiring layer adjacent to the wiring layer connected to the contact via 293) may increase. In some implementations, based on this positioning, edge placement error (EPE) in the patterning process may be reduced, thereby lowering process complexity, and time-dependent dielectric breakdown (TDDB) may be reduced, thereby improving the reliability of the semiconductor device.

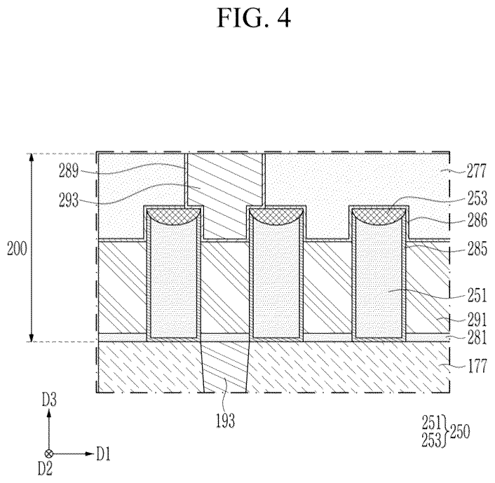

FIG. 4 is a cross-sectional view showing an example of a semiconductor device. The semiconductor device illustrated in FIG. 4 has many parts identical to or similar to that shown in FIGS. 1-3, so the following description focuses on the differences from the previous description. The semiconductor device illustrated in FIG. 4 may differ in some respects from the preceding semiconductor device in that it does not include the previously described air gap AG.

Referring to FIG. 4, in a semiconductor device, a separation structure 250 may be positioned between wiring layers 291. Specifically, in comparison to the semiconductor device described with reference to FIG. 1 to FIG. 3, the lower separation pattern 251 may be positioned at the location where the air gap AG was positioned in the semiconductor device of FIGS. 1 to 3. The semiconductor device may not include a second insulating liner 257 positioned on the side and bottom surface of the lower separation pattern 251.

Referring to FIG. 4, the lower surface of the lower separation pattern 251 may contact the upper surface of the interlayer insulating layer 277. In some implementations, a lower separation pattern 251 may be positioned between the wiring layers 291. In some implementations, the wiring layer 291 may entirely overlap with the lower separation pattern 251 in a horizontal direction (e.g., the first direction D1 or the second direction D2).

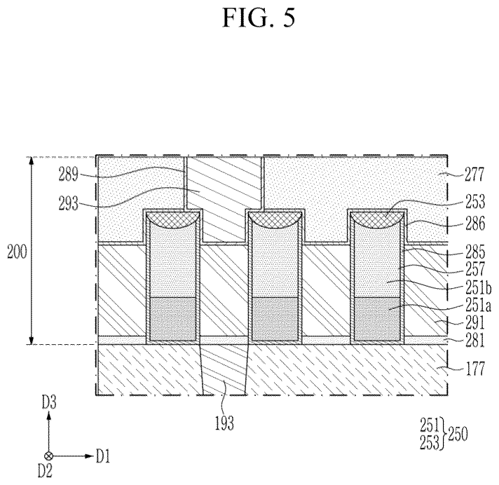

FIG. 5 is a cross-sectional view showing an example of a semiconductor device. The semiconductor device illustrated in FIG. 5 has many parts identical to or similar to the previous examples, so the following description focuses on the differences from the previous examples. The semiconductor device illustrated in FIG. 5 may differ in some respects from some implementations of the semiconductor devices of FIGS. 1 to 4 in that the lower separation pattern 251 includes two layers.

Referring to FIG. 5, in some implementations, the lower separation pattern 251 may include a first lower separation pattern 251a and a second lower separation pattern 251b positioned on the first lower separation pattern 251a. The first lower separation pattern 251a may be positioned where the air gap AG is positioned in the semiconductor device described with reference to FIG. 1 to FIG. 3. In some implementations, the upper surface of the first lower separation pattern 251a may contact the lower surface of the second lower separation pattern 251b. In some implementations, the interface of the first lower separation pattern 251a and the second lower separation pattern 251b may be positioned between the upper and lower surfaces of the wiring layer 291. In FIG. 5, the lower separation pattern 251 is depicted as consisting of two layers 251a and 251b, but the lower separation pattern 251 may include three or more layers.

In some implementations, the first lower separation pattern 251a may include an insulating material. In some implementations, the first lower separation pattern 251a may have a lower dielectric constant compared to the second lower separation pattern 251b. In some implementations, the first lower separation pattern 251a may include a low-k insulating material. For example, the first lower separation pattern 251a may include an insulating material having a lower dielectric constant than silicon oxide SiO₂. In some implementations, the first lower separation pattern 251a may include Al2O3. However, the material is not limited thereto, and the second insulating liner 257 may include various insulating materials such as silicon oxide SiO₂, silicon nitride (SiNₓ) or silicon oxide nitride (SiON).

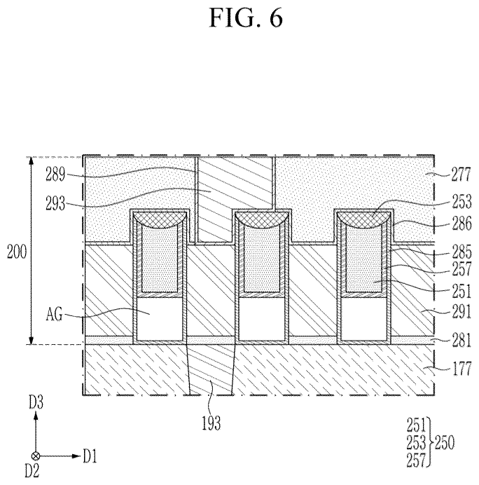

FIG. 6 is a cross-sectional view showing an example of a semiconductor device. The semiconductor device illustrated in FIG. 6 has many parts identical to or similar to the semiconductor devices described with respect to FIGS. 1 to 5, so the following description focuses on the differences therebetween. The semiconductor device illustrated in FIG. 6 may differ in some respects from some implementations of the previously-described examples in the position at which the contact via 293 is formed. For example, FIG. 6 may illustrate a semiconductor device in which a photomask is not precisely aligned during a process of etching a portion of an interlayer insulating layer 277 to form a contact via 293.

Referring to FIG. 6, contact via 293 may only cover a part of the upper surface of wiring layer 291. In some implementations, the contact via 293 may be positioned only on the upper surface of one of the two separation structures 250 located on either side of the wiring layer 291.

In some implementations, even if the contact via 293 is formed without the photomask being precisely aligned over the substrate 10, the contact via 293 may be sufficiently separated from the adjacent wiring layer (i.e., another wiring layer adjacent to the wiring layer connected to the contact via 293) by the separation structure 250.

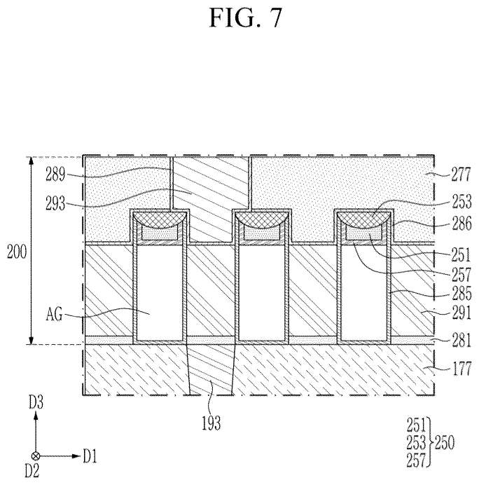

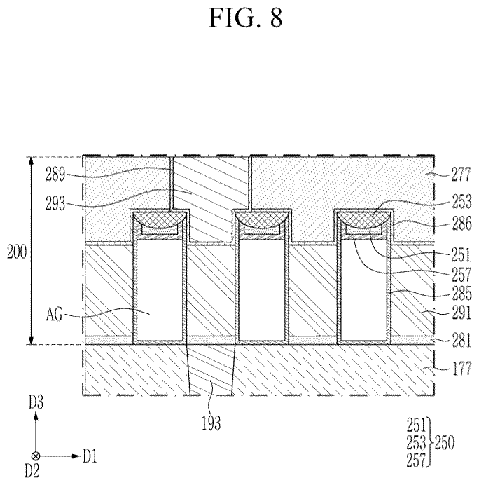

FIG. 7 and FIG. 8 are cross-sectional views showing examples of semiconductor devices. The semiconductor devices illustrated in FIG. 7 and FIG. 8 have many parts that are identical to or similar to the examples described with respect to FIGS. 1 to 6, so the following description focuses mainly on the differences from the previous examples. The semiconductor devices illustrated in FIG. 7 and FIG. 8 may have different positions of the air gap AG from previous examples.

For example, as shown in FIG. 7 and FIG. 8, the air gap AG may overlap an entirety of the wiring layer 291 in a horizontal direction (e.g., first direction D1, or second direction D2).

Referring to FIG. 7, the surface of the second insulating liner 257 in contact with the air gap AG may be positioned on the same plane as the upper surface of the wiring layer 291. Referring to FIG. 8, the surface of the second insulating liner 257 in contact with the air gap AG may be positioned at a level higher than the upper surface of the wiring layer 291. Accordingly, the air gap AG may overlap the entire region of the wiring layer 291 in the horizontal direction (e.g., first direction D1, or second direction D2), thereby reducing the parasitic capacitance around the wiring layer 291, and thus improving the electric characteristics of the semiconductor device.

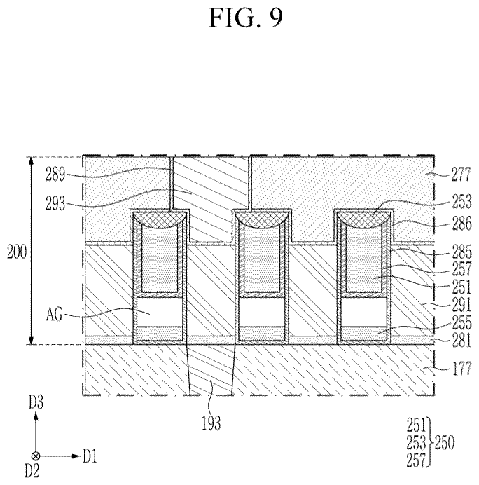

FIG. 9 is a cross-sectional view showing an example of a semiconductor device. The semiconductor device illustrated in FIG. 9 has many parts identical to or similar to the examples described with respect to FIGS. 1 to 8, so the following description focuses on the differences from the previous examples. The semiconductor device illustrated in FIG. 9 may differ from some implementations of the preceding examples in that it further includes an insulating pattern 255 positioned over an interlayer insulating layer 177.

In some implementations, insulation pattern 255 may be positioned between wiring layers 291. Referring to FIG. 9, the insulation pattern 255 may be positioned between the air gap AG and the interlayer insulating layer 177. The lower surface of the insulating pattern 255 may be in contact with the interlayer insulating layer 177, and the upper surface may be in contact with the air gap AG. Insulating pattern 255 may be formed by, in the process of forming the lower separation pattern 251, some of the insulating material included in the lower separation pattern 251 passing through the second insulating liner 257 and being piled up on the interlayer insulating layer 177, but is not limited thereto.

Insulating pattern 255 may include insulating material. In some implementations, the insulating pattern 255 may include the same insulating material as the lower separation pattern 251, but is not limited thereto. Insulating pattern 255 may include, for example, at least one of silicon oxide SiO₂, silicon nitride (SiNₓ), and silicon oxide nitride (SiON).

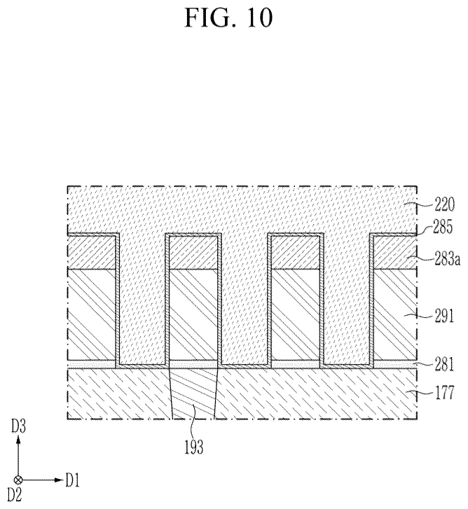

FIG. 10 to FIG. 21 are process cross-sectional views illustrating an example of a manufacturing method of semiconductor devices. Specifically, FIG. 10 to FIG. 21 are cross-sectional views corresponding to the ‘A’ region of FIG. 1. FIG. 10 to FIG. 21 illustrate process diagrams of intermediate stages of the manufacturing process.

As illustrated in FIG. 10, a plurality of wiring layers 291 and a sacrificial layer 220 covering the wiring layers 291 may be formed on a substrate that has undergone a FEOL (Front-end-of-Line) process. The FEOL (Front-end-of-Line) process may include a step of forming a transistor structure 100, a contact electrode 191, and a contact via 193 on a substrate 10 described with reference to FIG. 1 to FIG. 3, and a step of forming an interlayer insulating layer 177 covering them.

First, a conductive layer including a conductive material is deposited on an interlayer insulating layer 177 including a contact via 193, and then the conductive layer is patterned to form an adhesive layer 281 and a wiring layer 291 positioned on the adhesive layer 281. In some implementations, the conductive materials deposited on the interlayer insulating layer 177 may include a conductive material applicable to a subtractive patterning process. For example, the conductive material may include at least one of Ru, Al, W, Mo, Ti, Cr, and Ni.

For example, a conductive layer including a conductive material may be deposited on an interlayer insulating layer 177, and a hard mask pattern 283a as illustrated in FIG. 10 may be formed on a portion of the conductive layer. For example, hard mask pattern 283a may include silicon nitride (SiNₓ), but is not limited thereto.

Next, by etching a portion of the conductive layer formed on the interlayer insulating layer 177 using the hard mask pattern 283a as an etching mask, an adhesive layer 281 and a wiring layer 291 as shown in FIG. 10 may be formed. After this, a first insulating liner 285 may be formed that conformally covers the top and side surfaces of the hard mask pattern 283a, the upper surface of the interlayer insulating layer 177, and the side surfaces of the adhesive layer 281 and the wiring layer 291. Next, a sacrificial layer 220 may be entirely deposited on the upper surface of the first insulating liner 285 and the interlayer insulating layer 277. At this time, the sacrificial layer 220 may be deposited to a level higher than the upper surface of the hard mask pattern 283a so that the sacrificial layer 220 covers the entire region of the adhesive layer 281, the wiring layer 291, the hard mask pattern 283a, and the first insulating liner 285.

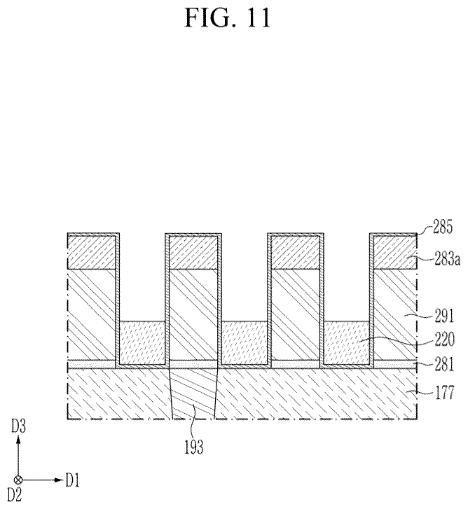

As illustrated in FIG. 11, a portion of the sacrificial layer 220 may be etched. For example, as illustrated in FIG. 11, a portion of the sacrificial layer 220 may be etched such that the upper surface of the sacrificial layer 220 is positioned at a level between the upper and lower surfaces of the wiring layer 291. Accordingly, the sacrificial layer 220 positioned in the region overlapping the wiring layer 291 and the third direction D3 is completely etched, and the sacrificial layer may be positioned in some regions between the wiring layers 291. The sacrificial layer 220 may be formed at a location where the air gap AG will be created in a subsequent process.

In some implementations, the sacrificial layer 220 may have a thickness different than that illustrated in FIG. 11. For example, in FIG. 11, the sacrificial layer 220 is formed so that its upper surface is positioned between the upper and lower surfaces of the wiring layer 291; however, in some implementations, the sacrificial layer 220 may be formed so that its upper surface is positioned at the same level as the upper surface of the wiring layer 291. As another example, the sacrificial layer 220 may be formed such that its upper surface is positioned between the upper surface of the wiring layer 291 and the upper surface of the hard mask pattern 283a.

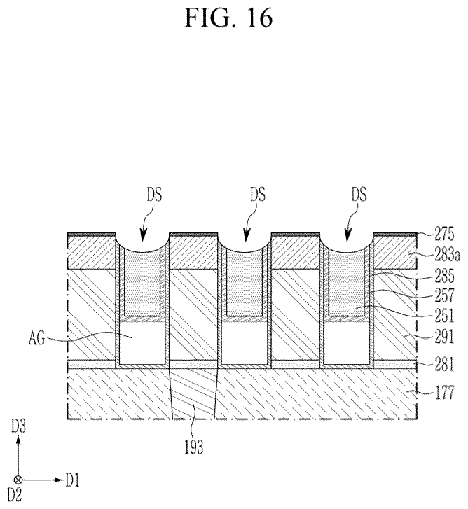

In some implementations, in a modification of the process of FIG. 10 and FIG. 11, the sacrificial layer 220 may be deposited from the beginning so that the upper surface of the sacrificial layer 220 is positioned at a specific level between the upper and lower surfaces of the wiring layer 291. For this purpose, a process may be added to form a deposition prevention layer (275, see FIG. 16) to be described later on the upper surface of the first insulating liner 285, which overlaps the wiring layer 291 in the third direction D3. In this case, the process of etching a part of the sacrificial layer 220, as described with reference to FIG. 11, may be omitted.

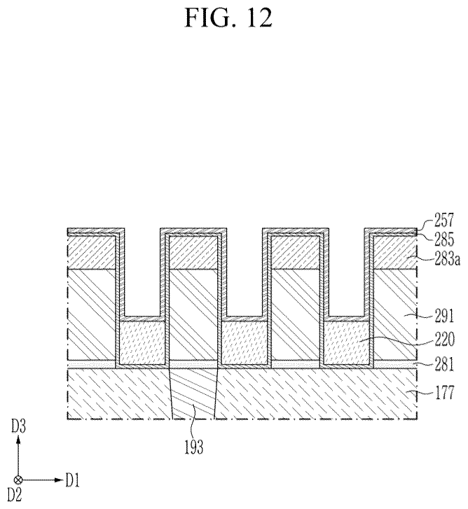

As illustrated in FIG. 12, a second insulating liner 257 may be formed on top of the sacrificial layer 220. A second insulating liner 257 may be formed to cover the upper surface of sacrificial layers 220 formed between wiring layers 291.

The second insulating liner 257 may cover the first insulating liner 285 positioned on the top and side surfaces of the hard mask pattern 283a. The second insulation liner 257 may cover the first insulation liner 285 positioned on a portion of the side region of the wiring layer 291.

The second insulating liner 257 may include an insulating material. The second insulating liner 257 may contain aluminum oxide (Al2O3). However, the material is not limited thereto, the second insulating liner 257 may include various insulating materials such as silicon oxide SiO₂, silicon nitride (SiNₓ) or silicon oxide nitride (SiON).

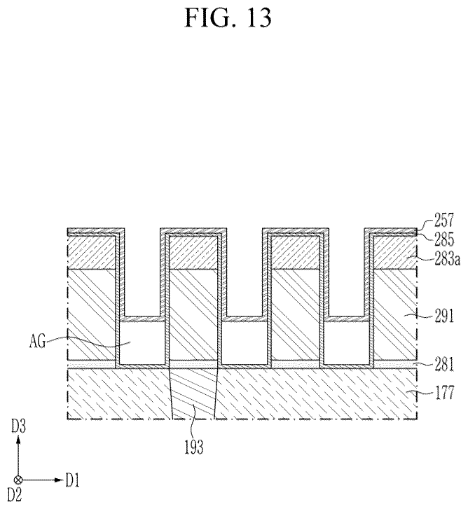

Next, as illustrated in FIG. 13, the sacrificial layer 220 positioned between the second insulating liner 257 and the interlayer insulating layer 177 may be removed. In some implementations, the sacrificial layer 220 may be removed by various methods. For example, the sacrificial layer 220 may be decomposed by performing heat treatment (annealing), ultraviolet rays irradiation, or plasma treatment. However, methods are not limited thereto, and, for example, sacrificial layer 220 may also be etched by wet etching, or dry etching. In some implementations, the layer constituting the second insulating liner 257 may be formed with a sufficiently low density to allow the sacrificial layer 220 to decompose and be released during the process of removing the sacrificial layer 220. As the sacrificial layer 220 is removed, an air gap AG may be formed between the interlayer insulating layer 177 and the second insulating liner 257.

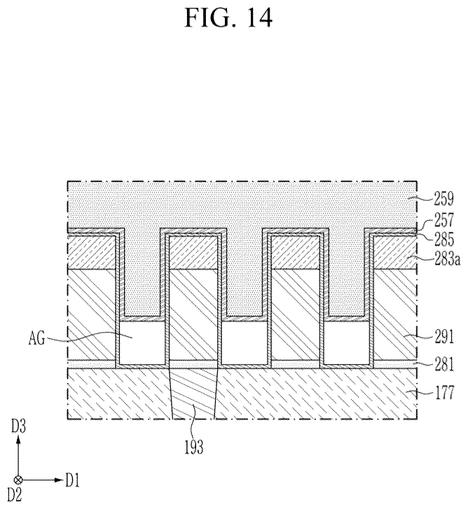

As illustrated in FIG. 14, an upper insulation layer 259 may be formed over a second insulation liner 257. The upper insulation layer 259 may cover the second insulation liner 257. Referring to FIG. 14, the upper insulation layer 259 may fill at least some region between a plurality of wiring layers 291. The upper insulation layer 259 may be formed between a plurality of wiring layers 291, over the second insulation liner 257.

The upper insulation layer 259 may not be formed inside the air gap AG. The second insulation liner 257 may prevent the upper insulation layer 259 from penetrating into the air gap AG during the process in which the upper insulation layer 259 is deposited. In some implementations, a pretreatment process, such as heat treatment, may be further performed on the second insulation liner 257 before depositing the upper insulation layer 259 to prevent the upper insulation layer 259 from penetrating into the air gap AG.

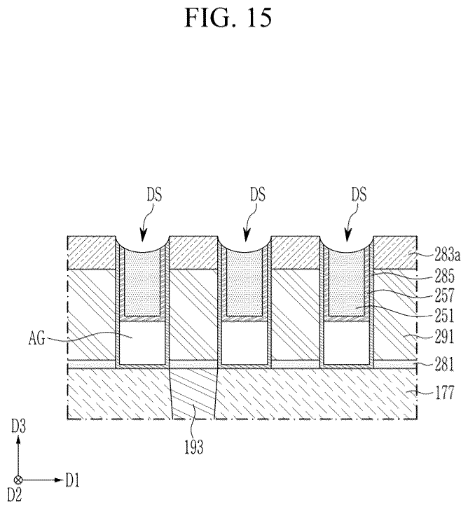

As illustrated in FIG. 15, a portion of the upper insulation layer 259 positioned at a higher level than the upper surface of the hard mask pattern 283a may be removed to form a lower separation pattern 251. In some implementations, the process of removing a portion of the upper insulation layer 259 may be performed by a chemical mechanical polishing process. The chemical mechanical polishing process may be performed until the upper surface of the upper insulation layer 259 is positioned at substantially the same level as the upper surface of the hard mask pattern 283a. In a chemical mechanical polishing process, an etching material having higher etch selectivity than the hard mask pattern 283a for the upper insulation layer 259 may be used. Referring to FIG. 15, a portion of the first insulation liner 285 and the second insulation liner 257, which are positioned at a level higher than the upper surface of the hard mask pattern 283a, may be removed together with the upper insulation layer 259 by a chemical mechanical polishing process.

In some implementations, a dishing region DS may be formed on the upper surfaces of the lower separation pattern 251, the first insulation liner 285, and the second insulation liner 257 by a chemical mechanical polishing process. Referring to FIG. 15, the lower separation pattern 251 may have a shape in which its upper surface is curved toward the upper surface of the interlayer insulating layer 177. The upper surface of the lower separation pattern 251 may have a surface profile in which the distance from the upper surface of the interlayer insulating layer 177 becomes increasingly closer from both ends to the center when viewed in cross-section.

In some implementations, process variables of a chemical mechanical polishing process may be controlled so that a dishing region DS has a predetermined depth. For example, the type and flow rate of slurry used in the chemical mechanical polishing process, process temperature, process time, etc. may be adjusted so that the dishing region DS has a predetermined depth. For example, the dishing region DS may have a depth greater than about ⅓ of the hard mask pattern 283a thickness. For example, the dishing region DS may have a depth shallower than the thickness of the hard mask pattern 283a. However, the depth is not limited to this, and the dishing region DS may be designed to have various depths.

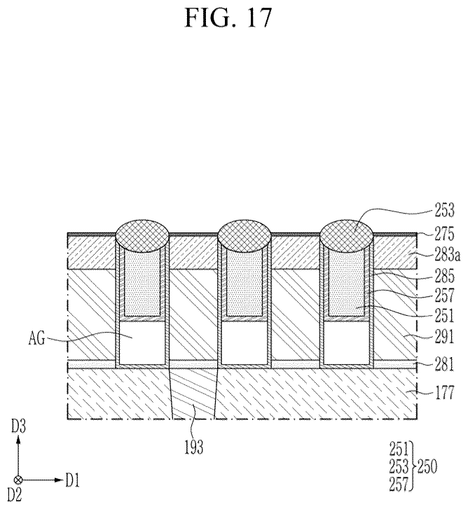

As illustrated in FIG. 16 and FIG. 17, the upper separation pattern 253 may be selectively formed over the lower separation pattern 251, the first insulation liner 285, and the second insulation liner 257. In some implementations, the process of forming the upper separation pattern 253 may be performed by an area selective deposition (ASD). The area selective deposition may be a process that selectively deposits a desired thin film on a specific region on a substrate.

First, as illustrated in FIG. 16, a deposition prevention layer 275 may be formed on the hard mask pattern 283a. The deposition prevention layer 275 may be formed using a material that may be selectively deposited only on the surface of a specific film. The deposition prevention layer 275 may be formed using an inhibitor, such as, for example, self-assembled monolayers (SAM) or small molecule Inhibitors (SMI). As illustrated in FIG. 16, the deposition prevention layer 275 may be selectively formed only on the upper surface of the hard mask pattern 283a. The deposition prevention layer 275 may not be formed on the surfaces of the lower separation pattern 251, the first insulation liner 285, and the second insulation liner 257.

Next, as illustrated in FIG. 17, an upper separation pattern 253 may be selectively formed on the upper surfaces of the lower separation pattern 251, the first insulation liner 285, and the second insulation liner 257. In some implementations, the upper separation pattern 253 may not be formed on the deposition prevention layer 275. In some implementations, the semiconductor device may not include the first insulating liner 285 and the second insulating liner 257, in which case the upper separator pattern 253 may be selectively formed only on the lower separation pattern 251.

In some implementations, the process of forming the upper separation pattern 253 may be performed using a precursor material that has no or relatively very low chemical affinity with the surface of the deposition barrier layer 275, while having relatively high chemical affinity with the surfaces of the lower separation pattern 251, the first insulating liner 285, and the second insulating liner 257.

For example, the lower separation pattern 251, the first insulating liner 285, and the second insulating liner 257 may include silicon oxycarbide (SiOC), in which case the area selective deposition process may be performed using a precursor material having a higher chemical affinity for silicon oxycarbide (SiOC) compared to the material included in the deposition barrier layer 275. In some implementations, the upper separation pattern 253 may be selectively formed only on the lower separation pattern 251, the first insulation liner 285, and the second insulation liner 257 by the area selective deposition process. In some implementations, the upper separation pattern 253 may not be formed on the deposition prevention layer 275.

In some implementations, the upper separation pattern 253 may fill the dishing region DS. In some implementations, as the upper separation pattern 253 is formed by filling the dishing region DS formed with a predetermined depth, the dishing region DS may prevent the upper separation pattern 253 from growing or depositing beyond the region that overlaps the lower separation pattern 251 in the third direction D3, into the region that overlaps the wiring layer 291 in the third direction D3. Accordingly, the upper separation pattern 253 may be stably formed only in the region overlapping specific patterns/layers (e.g., the lower separation pattern 251) in the third direction D3, e.g., and may be non-overlapping with the wiring layer 291.

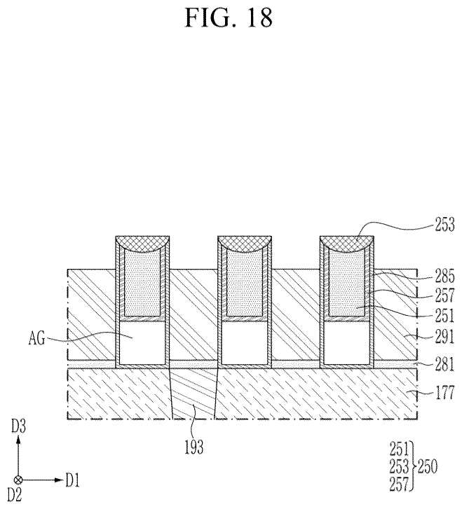

As illustrated in FIG. 18, the deposition prevention layer 275 and the hard mask pattern 283a may be removed. The process of removing the hard mask pattern 283a may be performed, for example, by a dry etching process. At this time, the upper region of the upper separation pattern 253 may also be partially removed. Referring to FIG. 18, after the dry etching process, the upper separation pattern 253 is depicted as having a flat shape on the upper surface, but the shape is not limited thereto. In some implementations, the process of removing the hard mask pattern 283a may be performed by, for example, a dry etching, a wet etching, or a cleaning process.

By completely removing the hard mask pattern 283a, the upper surface of the wiring layer 291 may be exposed, and a step may be formed between the upper surface of the wiring layer 291 and the upper surface of the upper separation pattern 253.

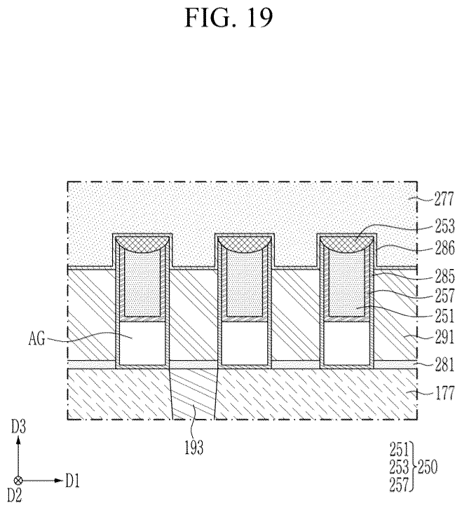

As illustrated in FIG. 19, an etching stop layer 286 and an interlayer insulating layer 277 may be sequentially formed on a wiring layer 291, a separation structure 250, and a first insulating liner 285. First, an etching stop layer 286 may be conformally deposited on the upper surface of the wiring layer 291, the upper surface of the separation structure 250, and the side surface of the first insulating liner 285. Next, an interlayer insulating layer 277 may be formed that entirely covers the etching stop layer 286.

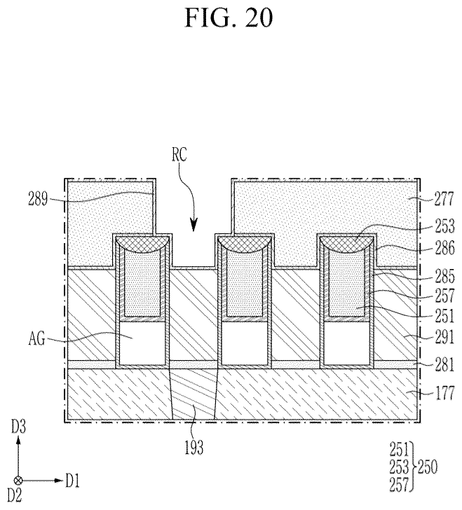

As illustrated in FIG. 20, a portion of the interlayer insulating layer 277, including a portion that overlaps the wiring layer 291 in the third direction D3, may be etched, and then a portion of the etching stop layer 286 may be etched to form a recess RC that exposes the upper surface of the wiring layer 291. Next, a barrier layer 289 may be conformally formed on the upper surface of the interlayer insulating layer 277 and the bottom surface and side surface inside the recess RC. The barrier layer 289 may include a conductive material. The barrier layer 289 may prevent the material included in the contact via 293 to be formed thereafter from diffusing into the interlayer insulating layer 277 and/or the separation structure 250. In some implementations, the process of forming the barrier layer 289 may be omitted.

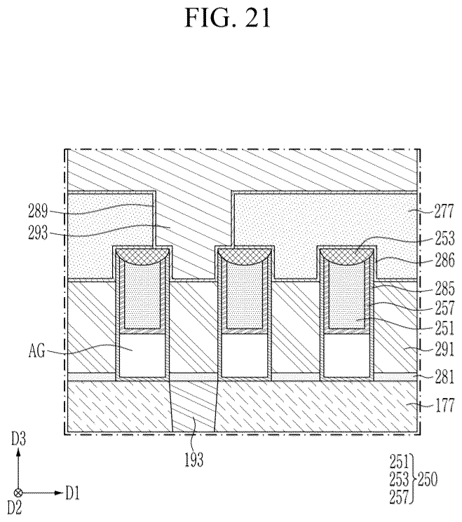

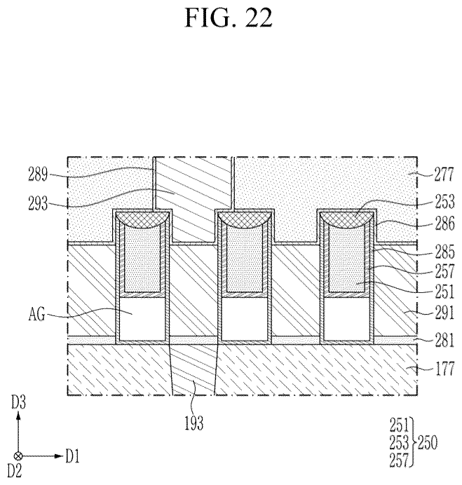

As shown in FIG. 21 and FIG. 22, the interior of the recess RC may be filled with a conductive material to form a contact via 293. First, as illustrated in FIG. 21, a conductive material may be formed inside the recess RC and on the upper surface of the interlayer insulating layer 277. After this, a chemical mechanical polishing process is performed to remove a portion of the barrier layer 289 and a portion of the contact via 293 positioned at a level higher than the upper surface of the interlayer insulating layer 277, thereby forming a contact via 293 as shown in FIG. 22.

The semiconductor device may include a plurality of wiring structures 200 stacked in the third direction D3. For example, another wiring structure may be positioned on the wiring structure (see 200 of FIG. 2) including a wiring layer and an interlayer insulating layer surrounding the wiring layer. In this case, the contact via 293 included in the wiring structure 200 and the wiring layer included in another wiring structure may be formed simultaneously. In this case, unlike what was described with reference to FIG. 21 and FIG. 22, a chemical mechanical polishing process may be performed so that the barrier layer 289 and the conductive material remain on the upper surface of the interlayer insulating layer 277. In this case, the barrier layer 289 and the conductive material remaining on the upper surface of the interlayer insulating layer 277 may form a part of another wiring structure positioned on the wiring structure 200.

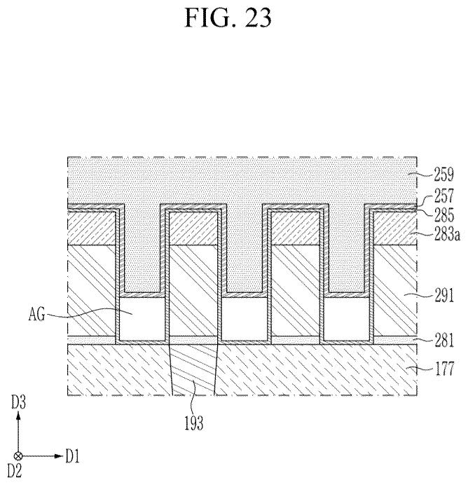

FIG. 23 to FIG. 30 are process cross-sectional views illustrating an example of a manufacturing method of semiconductor devices. Specifically, FIG. 23 to FIG. 30 are cross-sectional views corresponding to the ‘A’ region of FIG. 1, showing a manufacturing method of a semiconductor device according to an embodiment. Aspects of this method are identical or similar to those of the method of FIGS. 10 to 21, and, hereinafter, differences will be mainly described in comparison with the semiconductor device manufacturing method explained with reference to FIGS. 10 to 21.

First, as illustrated in FIG. 23, a plurality of wiring layers 291, a hard mask pattern 283a, a first insulating liner 285, a second insulating liner 257, and an upper insulation layer 259 may be formed on an interlayer insulating layer 177. In some implementations, an air gap AG may be positioned in some regions between wiring layers 291.

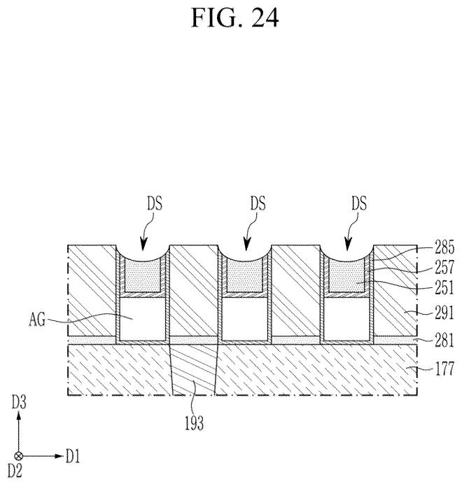

As illustrated in FIG. 24, a portion of the upper insulation layer 259 positioned at a higher level than the upper surface of the wiring layer 291 may be removed to form a lower separation pattern 251. Unlike the manufacturing method illustrated in FIG. 15, the upper insulation layer 259 positioned at a higher level than the upper surface of the wiring layer 291 may be removed by a chemical mechanical polishing process, using the upper surface of the wiring layer 291 as a reference. In the chemical mechanical polishing process, the hard mask pattern 283a positioned on the upper surface of the wiring layer 291 may also be removed.

The chemical mechanical polishing process may be performed until the upper surface of the upper insulation layer 259 is positioned at substantially the same level as the upper surface of the wiring layer 291. In a chemical mechanical polishing process, an etching material having higher etch selectivity for the upper insulation layer 259 and the hard mask pattern 283a than the wiring layer 291 may be used. Referring to FIG. 24, a portion of the first insulating liner 285 and the second insulating liner 257, which are positioned at a level higher than the upper surface of the wiring layer 291, and the hard mask pattern 283a may be removed together by a chemical mechanical polishing process.

In some implementations, a dishing region DS may be formed on the upper surfaces of the lower separation pattern 251, the first insulation liner 285, and the second insulation liner 257 by a chemical mechanical polishing process.

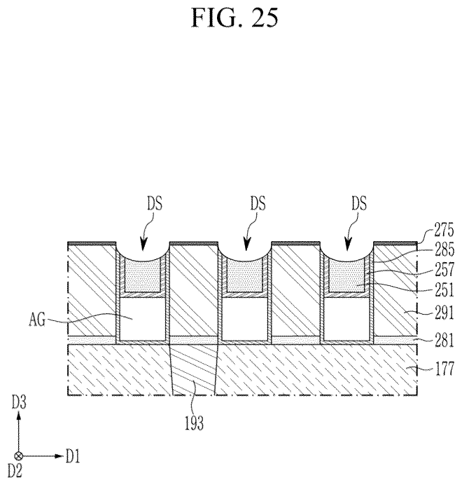

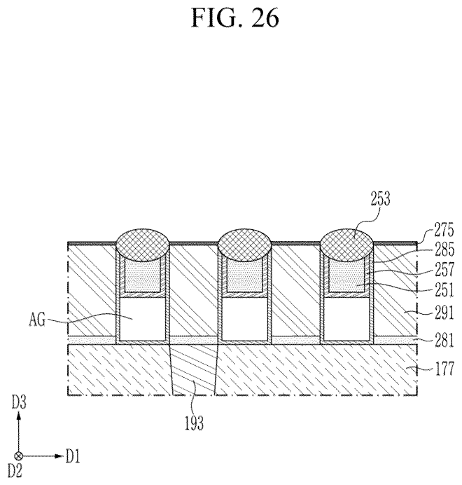

Next, as shown in FIG. 25 and FIG. 26, the upper separation pattern 253 may be selectively formed on the lower separation pattern 251, the first insulation liner 285, and the second insulation liner 257. In some implementations, the process of forming the upper separation pattern 253 may be performed by the area selective deposition process.

First, as illustrated in FIG. 25, a deposition prevention layer 275 may be formed on the upper surface of the wiring layer 291. The deposition prevention layer 275 may be selectively formed only on the upper surface of the wiring layer 291. The deposition prevention layer 275 may not be formed on the surfaces of the lower separation pattern 251, the first insulation liner 285, and the second insulation liner 257.

Next, as illustrated in FIG. 26, an upper separation pattern 253 may be selectively formed on the upper surfaces of the lower separation pattern 251, the first insulation liner 285, and the second insulation liner 257. In some implementations, the upper separation pattern 253 may fill the dishing region DS. In some implementations, the upper separation pattern 253 may not be formed over the deposition prevention layer 275. In some implementations, the process of forming the upper separation pattern 253 may be performed using a precursor material that has no or relatively little chemical affinity with the surface of the deposition barrier layer 275, while having relatively high chemical affinity with the surfaces of the lower separation pattern 251, the first insulating liner 285, and the second insulating liner 257.

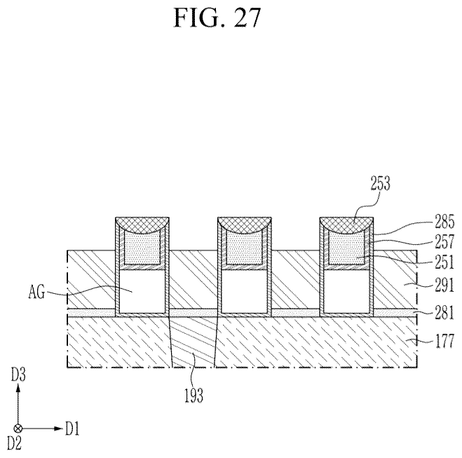

As illustrated in FIG. 27, a step may be formed between the separation structure 250 and the wiring layer 291 by removing a portion of the wiring layer 291. The process of removing the wiring layer 291 may be performed, for example, by a dry etching process. At this time, the upper separation pattern 253 may be used as a hard mask. In the process of etching the wiring layer 291, some regions of the upper separation pattern 253 may also be removed.

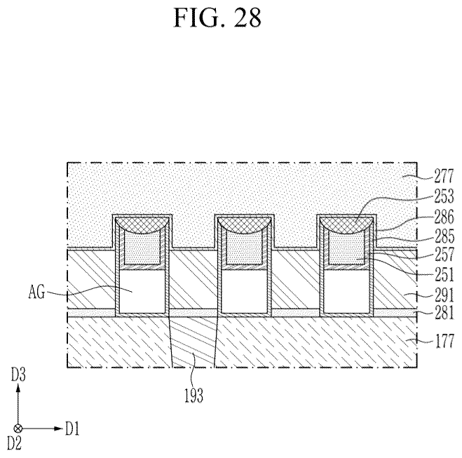

As illustrated in FIG. 28, an etching stop layer 286 and an interlayer insulating layer 277 may be sequentially formed on a wiring layer 291, a separation structure 250, and a first insulating liner 285.

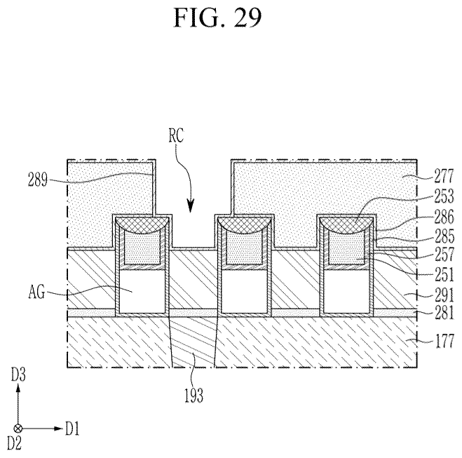

Next, as illustrated in FIG. 29, a portion of the interlayer insulating layer 277, including a portion overlapping the wiring layer 291 in the third direction D3, is etched, and then a portion of the etching stop layer 286 is etched to form a recess RC exposing the upper surface of the wiring layer 291. Next, a barrier layer 289 may be conformally formed on the upper surface of the interlayer insulating layer 277 and the bottom surface and side surface inside the recess RC.

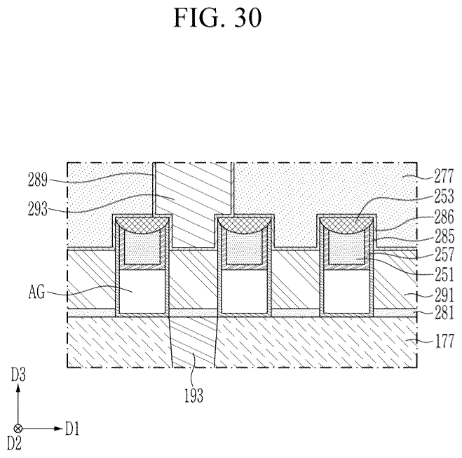

Next, as illustrated in FIG. 30, a conductive material is formed inside the recess RC and on the upper surface of the interlayer insulating layer 277, and then a chemical mechanical polishing process is performed to remove a portion of the barrier layer 289 and the contact via 293 positioned at a higher level than the upper surface of the interlayer insulating layer 277, thereby forming the contact via 293.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although examples have been described in detail above, the scope of the present disclosure is not limited thereto, and various modifications and improvements made by those skilled in the art also fall within the scope of the present disclosure.

What is claimed is:

1. A semiconductor device, comprising:
a substrate;
transistor structures on the substrate;
an interlayer insulating layer covering the transistor structures; and
a wiring structure on the interlayer insulating layer,
wherein the wiring structure comprises:
a plurality of wiring layers spaced apart from each other in a first direction, wherein the first direction is parallel to a surface of the substrate,
a separation structure between a pair of adjacent wiring layers of the plurality of wiring layers, wherein the separation structure comprises a lower separation pattern and an upper separation pattern, wherein the upper separation pattern is above the lower separation pattern, and
a contact via on a first wiring layer of the pair of adjacent wiring layers,
wherein an upper surface of the lower separation pattern includes a dishing region that is curved toward an upper surface of the interlayer insulating layer, and
wherein the upper separation pattern is within a recess formed by the dishing region.

2. The semiconductor device of claim 1, wherein an interface between a lower surface of the upper separation pattern and the upper surface of the lower separation pattern is positioned at a higher level than upper surfaces of the first wiring layer.

3. The semiconductor device of claim 1, wherein the upper separation pattern and the pair of adjacent wiring layers are non-overlapping with each other along a direction perpendicular to the upper surface of the interlayer insulating layer.

4. The semiconductor device of claim 1, comprising an air gap between the interlayer insulating layer and the separation structure.

5. The semiconductor device of claim 4, comprising an insulating liner between the air gap and the lower separation pattern.

6. The semiconductor device of claim 5, wherein a surface of the insulating liner in contact with the air gap is positioned at a same level as or higher than an upper surface of the first wiring layer.

7. The semiconductor device of claim 1, wherein an upper surface of the separation structure is positioned at a higher level than an upper surface of the first wiring layer.

8. The semiconductor device of claim 1, wherein a difference between (i) a vertical level at which an upper surface of the first wiring layer is positioned and (i) a vertical level at which an upper surface of the separation structure is positioned is greater than 0 nm and less than or equal to 10 nm.

9. The semiconductor device of claim 1, wherein the contact via covers:
at least a portion of an upper surface of the first wiring layer, and
at least a portion of an upper surface of the separation structure.

10. The semiconductor device of claim 1, wherein a width of the contact via along the first direction at a level higher than an upper surface of the separation structure, is greater than a width of the first wiring layer along the first direction.

11. The semiconductor device of claim 1, wherein the upper separation pattern includes an insulating material having a dielectric constant lower than a dielectric constant of SiO₂.

12. The semiconductor device of claim 1, wherein the upper separation pattern includes at least one of SiOC, SiOₓ, AlOₓ, AlSiOₓ, or ZrOₓ.

13. The semiconductor device of claim 1, wherein the lower separation pattern includes:
a first lower separation pattern on the interlayer insulating layer, and
a second lower separation pattern between the first lower separation pattern and the upper separation pattern,
wherein the first lower separation pattern includes an insulating material having a dielectric constant lower than a dielectric constant of SiO₂.

14. The semiconductor device of claim 1, wherein the pair of adjacent wiring layers include at least one of Ru, W, or Mo.

15. The semiconductor device of claim 1, wherein a ratio of (i) a greatest distance, in a vertical direction perpendicular to the upper surface of the interlayer insulating layer, between a top surface of the upper separation pattern and a bottom surface of the upper separation pattern, to (ii) a distance between the top surface of the upper separation pattern is located and a top surface of the first wiring layer, is in a range from 0.3 to 1.0.

16. A semiconductor device comprising:
a substrate;
transistor structures on the substrate;
an interlayer insulating layer covering the transistor structures; and
a wiring structure positioned on the interlayer insulating layer,
wherein the wiring structure comprises:
a plurality of wiring layers spaced apart from each other in a first direction, wherein the first direction is parallel to a surface,
a separation structure between a pair of adjacent wiring layers of the plurality of wiring layers,
an air gap between the interlayer insulating layer and the separation structure, and
an insulating liner between the air gap and the separation structure,
wherein a surface of the insulating liner in contact with the air gap is positioned at a same level as or higher than an upper surface of a first wiring layer of the pair of adjacent wiring layers.

17. The semiconductor device of claim 16, wherein:
the separation structure comprises a lower separation pattern and an upper separation pattern, wherein the upper separation pattern is above the lower separation pattern,
an upper surface of the lower separation pattern includes a dishing region, wherein the dishing region is curved toward an upper surface of the interlayer insulating layer, and
the upper separation pattern is positioned within a recess formed by the dishing region.

18. The semiconductor device of claim 17, wherein the upper separation pattern and the pair of adjacent wiring layers are non-overlapping along a direction perpendicular to an upper surface of the interlayer insulating layer.

19. The semiconductor device of claim 16, wherein the contact via covers:
at least a portion of the upper surface of the first wiring layer, and
at least a portion of an upper surface of the separation structure.

20. A semiconductor device comprising:
a substrate;
transistor structures on the substrate;
a first interlayer insulating layer covering the transistor structures; and
a wiring structure on the first interlayer insulating layer,
wherein the wiring structure comprises:
a plurality of wiring layers spaced apart from each other in a first direction, wherein the first direction is parallel to a of the substrate,
a separation structure between a pair of adjacent wiring layers of the plurality of wiring layers,
wherein the separation structure includes a lower separation pattern and an upper separation pattern on the lower separation pattern, and
wherein an upper surface of the separation structure is positioned at a higher level than an upper surface of a first wiring layer of the pair of adjacent wiring layers,
an insulating liner covering a side surface and a lower surface of the lower separation pattern,
a second interlayer insulating layer covering:
at least a portion of the upper surface of the first wiring layer, and
at least a portion of each of the upper surface and a side surface of the separation structure,
a contact via extending in the second interlayer insulating layer and electrically connected to the first wiring layer,
wherein the contact via, at a level higher than the upper surface of the separation structure, has a width along the first direction greater than a width of the first wiring layer along the first direction, and
wherein the contact via covers at least a portion of the upper surface of the first wiring layer and at least a portion of the upper surface of the separation structure, and
a barrier layer covering a side surface and a lower surface of the contact via,
wherein an air gap is between a lower surface of the separation structure and the first interlayer insulating layer,
wherein an upper surface of the lower separation pattern includes a dishing region, wherein the dishing region is curved toward an upper surface of the first interlayer insulating layer, and
wherein the upper separation pattern is within a recess formed by the dishing region.
